(19) United States
(12) Patent Application Publication
(10) Pub. No.: US 2011/0186799 A1
(43) Pub. Date: Aug. 4, 2011

(54) NON-VOLATILE MEMORY CELL CONTAINING NANODOTS AND METHOD OF MAKING THEREOF

(75) Inventors: James Kai, Santa Clara, CA (US); Henry Chien, San Jose, CA (US); George Matamis, San Jose, CA (US)

(73) Assignee: SanDisk 3D LLC, Milpitas, CA (US)

(21) Appl. No.: 13/020,054

(22) Filed: Feb. 3, 2011

Related U.S. Application Data
(60) Provisional application No. 61/282,408, filed on Feb. 4, 2010.

(51) Int. Cl. H01L 29/04; H01L 21/16; H01L 23/52; B82Y 99/00

(52) U.S. Cl. 257/3; 438/104; 257/746; 257/E29.003; 257/E21.078; 257/E23.141; 977/774

(57) ABSTRACT

A non-volatile memory cell includes a first electrode, a steering element, a storage element located in series with the steering element, a plurality of discrete conductive nano-features separated from each other by an insulating matrix, where the plurality of discrete nano-features are located in direct contact with the storage element, and a second electrode. An alternative non-volatile memory cell includes a first electrode, a steering element, a storage element located in series with the steering element, a plurality of discrete insulating nano-features separated from each other by a conductive matrix, where the plurality of discrete insulating nano-features are located in direct contact with the storage element, and a second electrode.

### CROSS-REFERENCE TO RELATED APPLICATIONS

The present application claims the priority benefit of U.S. provisional patent application 61/282,408, filed on Feb. 4, 2010, which is incorporated herein by reference in its entirety.

### BACKGROUND OF THE INVENTION

The invention relates to non-volatile memory devices and methods of making thereof.

Non-volatile memory arrays maintain their data even when power to the device is turned off. In one-time programmable arrays, each memory cell is formed in an initial unprogrammed state, and can be converted to a programmed state. This change is permanent, and such cells are not erasable. In other types of memories, the memory cells are erasable, and can be rewritten many times.

Cells may also vary in the number of data states each cell can achieve. A data state may be stored by altering some characteristic of the cell which can be detected, such as current flowing through the cell under a given applied voltage or the threshold voltage of a transistor within the cell. A data state is a distinct value of the cell, such as a data ‘0’ or a data ‘1’.

### SUMMARY OF THE EMBODIMENTS

One embodiment of the invention provides a non-volatile memory cell, comprising a first electrode, a steering element, a storage element located in series with the steering element, a plurality of discrete conductive nano-features separated from each other by an insulating matrix, where the plurality of discrete nano-features are located in direct contact with the storage element, and a second electrode.

Another embodiment of the invention provides a method of making a non-volatile memory cell, comprising forming a first electrode, forming a steering element, forming a storage element, forming a plurality of discrete conductive nano-features separated from each other by an insulating matrix, where the plurality of discrete conductive nano-features are located in direct contact with the storage element, and forming a second electrode.

Another embodiment of the invention provides a non-volatile memory cell, comprising a first electrode, a steering element, a storage element located in series with the steering element, a plurality of discrete insulating nano-features separated from each other by a conductive matrix, where the plurality of discrete insulating nano-features are located in direct contact with the storage element, and a second electrode.

Another embodiment of the invention provides a method of making a non-volatile memory cell, comprising forming a first electrode, forming a steering element, forming a storage element, forming a plurality of discrete insulating nano-features separated from each other by a conductive matrix, where the plurality of discrete insulating nano-features and the conductive matrix are located in direct contact with the storage element, and forming a second electrode.

### BRIEF DESCRIPTION OF THE DRAWINGS

FIG. 1 is a perspective view of a non-volatile memory cell of one embodiment.

FIG. 2 is a side cross-sectional view illustrating a non-volatile memory cell of one embodiment.

FIGS. 3A through 3C are side cross-sectional views illustrating stages in formation of the non-volatile memory cell shown in FIG. 2.

FIGS. 4A and 4B are side cross-sectional views illustrating stages in formation of a non-volatile memory cell of another embodiment.

FIGS. 5A and 5B are side cross-sectional views illustrating switching mechanisms of the non-volatile memory cells of different embodiments.

FIGS. 6A and 6B are side cross-sectional views illustrating non-volatile memory cells of alternative embodiments.

### DETAILED DESCRIPTION OF THE PREFERRED EMBODIMENTS

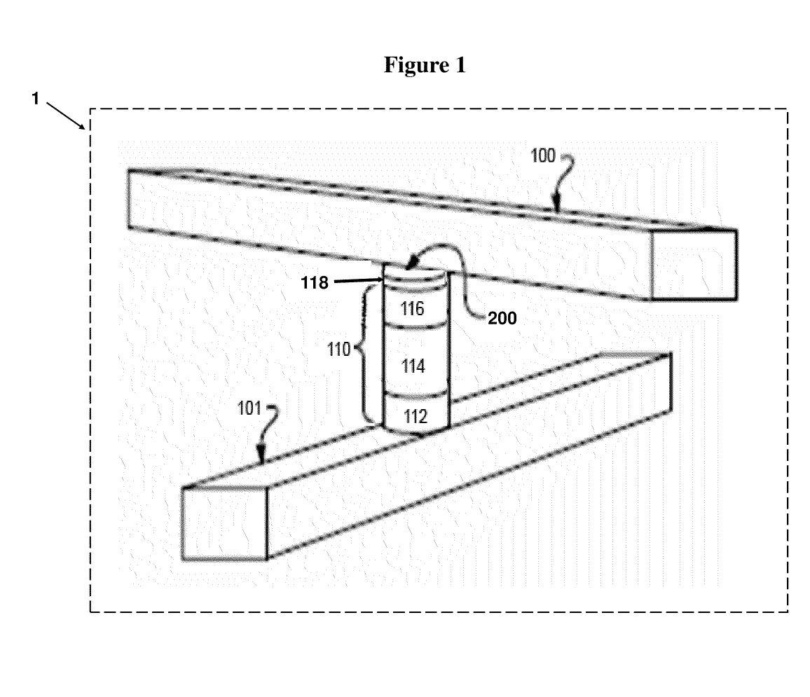

In general, a memory cell comprises a storage element and a steering element. For example, FIG. 1 illustrates a perspective view of a memory cell 1 of one embodiment.

The cell 1 includes a first electrode 101 and a second electrode 100 are formed of a conductive material, which can independently comprise any one or more suitable conducting material known in the art, such as tungsten, copper, aluminum, tantalum, titanium, cobalt, titanium nitride or alloys thereof. For example, in some embodiments, tungsten is preferred to allow processing under a relatively high temperature. In some other embodiments, copper or aluminum is a preferred material. The first electrode 101 extends in a first direction while the second electrode 100 extends in a second direction different from the first direction. Barrier and adhesion layers, such as TiN layers, may be included in the first (e.g., the bottom) electrode 101 and/or the second (e.g., the top) electrode 100.

The steering element 110 can be a transistor or a diode. If the steering element 110 is a diode, the storage element can be arranged vertically and/or horizontally and/or patterned to form a pillar or block having a substantially cylindrical shape. In one embodiment, as shown in FIG. 1, the steering element 110 is a semiconductor diode arranged vertically and having a bottom heavily doped n-type region 112, an optional intrinsic region 114, which is not intentionally doped, and a top heavily doped p-type region 116, though the orientation of this diode may be reversed. Such a diode, regardless of its orientation, will be referred to as a p-i-n diode or simply diode. The diode can comprise any single crystal, polycrystalline, or amorphous semiconductor material, for example silicon, germanium, silicon germanium, or other compound semiconductor materials, such as III-V, II-VI, etc. materials.

A storage element 118 is disposed in series with the steering element 110, either over the top region 116 or below the bottom region 112 of the steering element 110. The storage element 118 may be a resistivity switching element. In some other embodiments, the storage element is a resistivity switching element comprising at least one of switchable metal oxide, complex metal oxide layer, carbon nanotube material, graphene resistivity switchable material, carbon resistivity switchable material, phase change material, conductive bridge element, or switchable polymer material. For example, the storage element may comprise a metal oxide switchable material selected from the group consisting of NiO, Nb₂O₅, TiO₂, HfO₂, Al₂O₃, MgOₓ, CrO₂, VO or the combination thereof.

In preferred embodiments of this invention, a layer 200 comprising nano-features disposed in direct contact (i.e., physical and electrical contact) with the storage element 118. The layer 200 preferably comprises a plurality of discrete conductive nano-features separated from each other by a insulating matrix. In an alternative embodiment, the layer 200 comprises a plurality of discrete insulating nano-features separated from each other by a conductive matrix. Preferably, the conductive nano-features or the conductive matrix electrically contact electrode 100 or 101.

One advantage of including the layer 200 of nano-features in direct contact with the storage element 118 is that the electrical contact area of the electrode 100 or 101 to the storage element 118 can be minimized. When the memory cell is programmed, the conduction paths may be formed only in the electrical contact area (i.e., only through the portion of the storage element 118 located adjacent to the conductive nano-features or conductive matrix of the layer 200). For the same reasons, the leakage current through damaged switching material at the cell edge may also be reduced, compared to that of conventional non-volatile memory cells. The distribution of cell current may be more uniform across the cell area.

Second, by controlling the size and density of the nano-features, the number of contact points per memory cell may be easily controlled, which is a difficult task in the conventional technology of non-volatile memory cells.

Third, in some embodiments, because higher electric field will be formed around the sharp curvature of the conductive nano-features, the storage element may be programmed by smaller set and/or reset voltages.

Further, the insulating (i.e., dielectric) matrix between the conductive nano-features lowers the electric field in the switching material, thus lowering the leakage current and the chance of forming additional conduction paths.

Finally, with such nano-features located in direct contact with the storage element, it is also possible to optimize the leakage current and switching characteristics of the non-volatile memory cells independently.

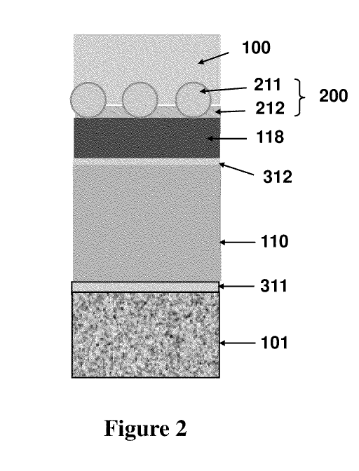

In one embodiment, the layer 200 may comprise a plurality of discrete conductive nano-features 211 separated from each other by an insulating matrix 212, as shown in FIG. 2. The plurality of discrete nano-features 211 are located in direct (i.e., physical and electrical) contact with the storage element 118, and in electrical contact with the second electrode 100. Optional conductive barrier layers 311 and 312 may be disposed between the first electrode 101 and the diode 110, and/or between the diode 110 and the switching material 118. One or more conductive barrier layers (not shown) may be disposed between the nano-features 211 and the second electrode 100.

The plurality of discrete conductive nano-features 211 may be made of any semiconductor material. Preferably, the semiconductor material is relatively highly conductive, such as a heavily doped semiconductor material having a dopant concentration about 1×10¹⁷ cm⁻³. Non-limiting examples of the semiconductor material include silicon, germanium, silicon germanium, other IV-IV semiconductors such as SiC, IV-VI semiconductors such as PbSe or PbS, III-V semiconductors such as GaAs, GaN, InP, GaSb, InAs, GaP, etc., or ternary and quaternary alloys thereof, or II-VI semiconductors such as ZnSe, ZnS, ZnTe, CdTe, CdTe, CdS, etc., or ternary and quaternary alloys thereof. Alternatively, the plurality of discrete conductive nano-features 211 may be made of any suitable metallic materials, such as noble metals (e.g., Au, Pt, Ag, Pd, Rh, Ru, etc.), any other metals (e.g., W, Cu, Al, Ta, Ti, Co, V, Cr, Mn, Fe, Zn, Zr, Nb, Mo, etc.), any conductive metal alloys, including conductive metal oxide or nitride (e.g., indium tin oxide, indium oxide, aluminum zinc oxide, ZnO, TiN), or silicide, such as titanium, nickel, cobalt or other silicides, or any conductive polymers.

The insulating matrix 212 may be made of any electrically insulating material, such as silicon oxide, silicon nitride, silicon oxynitride, or other high-k insulating materials, such as polymer or organic materials, or inorganic materials such as Al₂O₃, HfO₂, Ta₂O₅, etc.

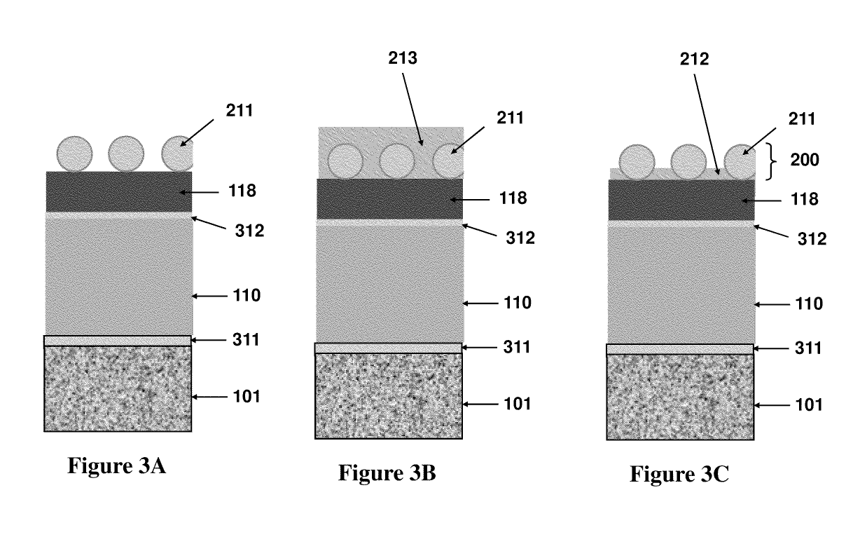

FIGS. 3A through 3C show side cross-sectional views illustrating stages in formation of a memory device shown in FIG. 2.

Referring to FIG. 3A, a first electrode 101 is formed over a substrate (not shown). The substrate can be any semiconducting substrate known in the art, such as monocrystalline silicon, IV-IV compounds such as silicon-germanium or silicon-germanium-carbon, III-V compounds, II-VI compounds, epitaxial layers over such substrates, or any other semiconducting or non-semiconducting material, such as glass, plastic, metal or ceramic substrate. The substrate may include integrated circuits fabricated thereon, such as driver circuits for a memory device.

An optional barrier layer 311 (e.g., TiN barrier layer) is then formed over the first electrode 101, followed by forming a steering element 110 over the optional barrier layer 311. An optional barrier layer 312 is formed over the steering element 110. Then the storage element 118 is formed over the optional barrier layer 312.

Next, a plurality of discrete conductive nano-features 211 are formed over the storage element 118. Preferably, the nano-features 211 are separated from each other (i.e., preferably not contacting each other). The conductive nano-features 211 may have any desirable size and shape. In a preferred embodiment, conductive nano-features 211 are conductive nanodots (also known as nanoparticles) having a substantially spherical shape and a diameter of less than 20 nm, for example less than 10 nm, such as 2-10 nm. In some embodiments, the conductive nanodots 211 may have a curved contact area of about 2 nm to about 3 nm with the storage element 118. The nanodots may be deposited by any known deposition method, such as spay or dip coating pure nanodots or nanodot ligand complexes.

In a non-limiting example, the conductive nanodots have a diameter of around 4 nm and a density of about 9 nanodots per a 24×24 nm² memory cell. In this non-limiting example, the electric contact area may be estimated to be less than about 113.09 nm² (i.e., the total area of top cross-section of the nanodots) per memory cell. Further, when programmed, conduction path may not form through all of the 9 nanodots, because once conduction paths are formed through first 2 or 3 nanodots, additional conduction paths might not be able to form through other nanodots anymore.

Turning to FIG. 3B, an insulating layer 213 is formed over and between the plurality of discrete, conductive nano-features 211. The insulating layer 213 may be formed by any suitable methods, for example by physical vapor deposition, chemical vapor deposition or spin on technologies. Preferably, the insulating layer 213 can be formed by a low temperature and conformal deposition, for example an atomic layer deposition of a silicon oxide, flowable oxide deposition, or other suitable insulating materials. Other insulating materials described above may also be used. For example, flowable oxides are available under the name Black-Diamond™ dielectric, available from Applied Materials, Santa Clara, Calif. Other flowable insulating materials include polymer materials, such as various polyimides, FLARE 2.0™ dielectric ((apoly(arylene)ether) available from Allied Signal, Advanced Microelectronic Materials, Sunnyvale, Calif.), etc.

Next, an upper portion of the insulating layer 213 is removed (e.g., etched back or polished back) to expose the plurality of conductive nano-features 211. A lower portion of the insulating layer 213 remains between the plurality of conductive nano-features 211 after the step of removing the upper portion of the insulating layer 213 to form the insulating matrix 212, as shown in FIG. 3C. The insulating layer 213 may be etched by any suitable methods. In preferred embodiments, anisotropic etching methods may be used. In a non-limiting example, SICONI™ etching method may be used to selectively etch the upper portion of the insulating layer 213, exposing the nano-features.

Next, the second electrode 100 can then be formed over the layer 200 (i.e., the plurality of conductive nano-features 211 separated from each other by the insulating matrix 212), resulting in the structure shown in FIG. 2. Electrode 100 electrically (or electrically and physically) contacts nano-features 211.

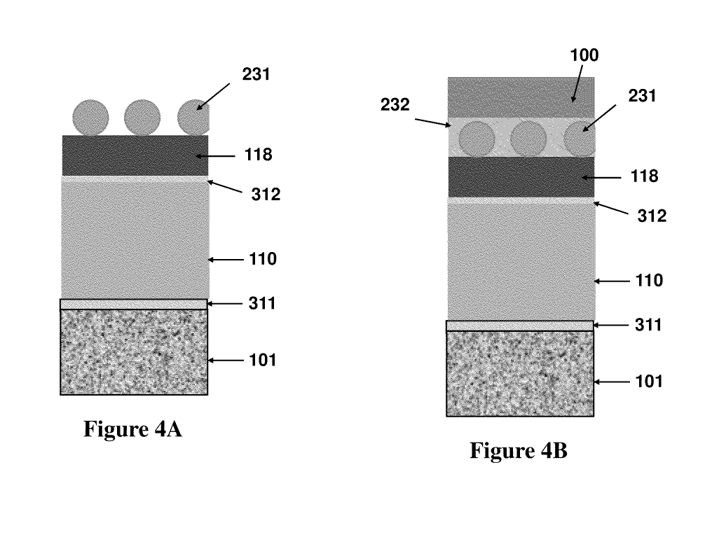

In an alternative embodiment, rather than forming the plurality of discrete conductive nano-features 211 separated from each other by the insulating matrix 212, the layer 200 may comprise a plurality of discrete insulating nano-features 231 separated from each other by a conductive matrix 232, as shown in FIGS. 4A and 4B.

In this alternative embodiment, rather than forming conductive nano-features 211 described above, discrete insulating nano-features 231 are first formed over the storage element 118, as shown in FIG. 4A. The insulating nano-features 231 may comprise any electrically insulating material, such as silicon oxide, silicon nitride, silicon oxynitride, or other high-k insulating materials, such as polymer or organic materials, or inorganic materials such as Al₂O₃, HfO₂, Ta₂O₅, etc. The insulating nano-features 231 may have any desired size and shape. In a preferred embodiment, the insulating nano-features 231 have a substantially spherical shape and a diameter of less than 20 nm, for example less than 10 nm, such as 2-10 nm. In a non-limiting example, the insulating nano-features 231 comprise silicon oxide nanodots having a diameter of around 4 nm. An conductive matrix 232 is then formed over and between the discrete, insulating nano-features 231, followed by forming the second electrode 100 over the conductive matrix 232, resulting in a structure shown in FIG. 4B. The conductive matrix 232 is in electrical or electrical and physical contact with the storage element 118 and the electrode 100. The conductive matrix 232 and the second electrode 100 may comprise the same or different conductive materials, and may be formed by a single step or different steps. For example, the conductive matrix may comprise any one or more suitable conducting materials known in the art, such as metals or metal alloys, including metal nitrides, oxides or silicides, as described above, and including but not limited to tungsten, copper, aluminum, tantalum, titanium, cobalt, titanium nitride or alloys thereof.

This alternative embodiment has advantages similar to the first embodiment of conductive nano-features separated from each other by the insulating matrix. For example, the electrical contact area of the electrode 100 or 101 to the storage element 118 can be minimized, and when the memory cell is programmed, the conduction paths may be formed only in the electrical contact area (i.e., only through the portion of the storage element 118 located adjacent to the conductive matrix of the layer 200). For the same reasons, the leakage current through damaged switching material at the cell edge may also be reduced, compared to that of conventional non-volatile memory cells. The distribution of cell current may be more uniform across the cell area. Furthermore, by controlling the size and density of the insulating nano-features 231, the size of contact area of memory cell may be easily controlled, which is a difficult task in the conventional technology of non-volatile memory cells. The insulating (i.e., dielectric) nano-features lower the electric field in the switching material, thus lowering the leakage current and the chance of forming additional conduction paths. Finally, with the insulating nano-features and conductive matrix located in direct contact with the storage element, it is also possible to optimize the leakage current and switching characteristics of the non-volatile memory cells independently.

The above described nano-features 211 (or 231) can be formed by any suitable methods. For example, in one embodiment, the nano-features 211 (or 231) can be formed by applying a dispersion of nanodots in a solvent over the storage element 118, followed by removing the solvent. In this embodiment, the size of nanodots 211 (or 231) and the spacing between the conductive nanodots 211 (or 231) can be easily tuned by varying the ligand chemistry.

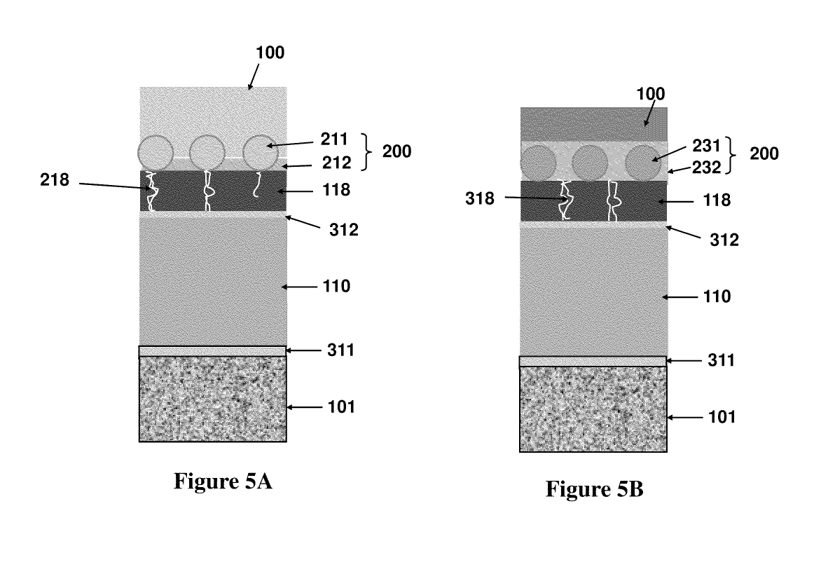

In one non-limiting embodiment, the storage element comprises a metal oxide resistivity switching material, such as NiO, Nb₂O₅, TiO₂, HfO₂, Al₂O₃, MgO,ₓ, CrO₂, VO or the combination thereof. Without wishing to be bound by a particular theory, the switching mechanism of the non-volatile memory cell 1 includes formation of filaments 218 through the metal oxide storage element 118, as shown in FIGS. 5A and 5B. The filaments 218 are only formed through the storage element 118 adjacent to (i.e., directly below) the discrete conductive nano-features 211 when the non-volatile memory cell 1 is programmed, as shown in FIG. 5A. In the alternative embodiment, as shown in FIG. 5B, the filaments 318 are only formed through the storage element 118 adjacent to the conductive matrix 232 when the alternative non-volatile memory cell 1 is programmed. No filaments are formed adjacent to the insulating nano-features 231.

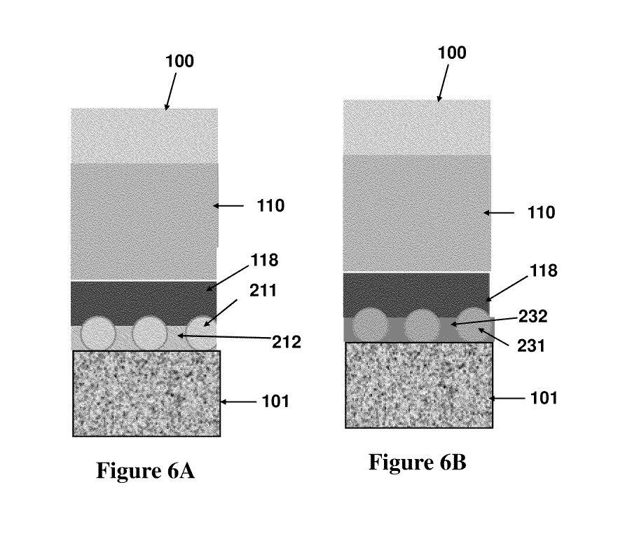

In the above described examples, the layer 200 is located above the storage element 118. However, the layer 200 may also be located below the storage element 118, for example as shown in FIGS. 6A and 6B. Specifically, FIG. 6A shows an example having a plurality of discrete conductive nano-features 211 separated from each other by a insulating matrix 212 that are located above the first electrode 101, a storage element 118 located above and in direct contact with the plurality of discrete conductive nano-features 211, a steering element 110 located above the storage element 118, and the second electrode 100 located above the steering element 110. FIG. 6B shows another example having a plurality of discrete insulating nano-features 231 separated from each other by a conductive matrix 232 located above the first electrode 101, a storage element 118 located above and in direct contact with the plurality of discrete insulating nano-features 231 and conductive matrix 232, a steering element 110 located above the storage element 118, and the second electrode 100 located above the steering element 110.

Of course, other configurations (not shown) may also be formed. For example, the layer 200 (i.e., the plurality of discrete conductive nano-features 211 separated from each other by the insulating matrix 212, or the plurality of discrete insulating nano-features 231 separated from each other by the conductive matrix 232) may be formed between the steering element 110 and the storage element 118, rather than between the storage element 118 and the electrodes 101 or 100, as described above. In this configuration, the steering element 110 may be located either above or below the storage element 118 with the layer 200 located in between elements 110 and 118. One or more of the optional conductive barrier layers described above may also be used in this configuration. For example, one barrier layer may be located between the steering element 110 and the layer 200.

In preferred embodiments, the memory cell 1 includes a cylindrical steering element 110 and storage element 118, as shown in FIG. 1. However, the steering element 110 and storage element 118 may have a shape other than cylindrical, such as rail shaped, if desired. For a detailed description of a the design of a memory cell, see for example U.S. patent application Ser. No. 11/125,939 filed on May 9, 2005 (which corresponds to US Published Application No. 2006/0250836 to Herner et al.), and U.S. patent application Ser. No. 11/395,995 filed on Mar. 31, 2006 (which corresponds to US Patent Published Application No. 2006/0250837 to Herner et al.,), each of which is hereby incorporated by reference.

The memory cell 1 can be a read/write memory cell or a rewritable memory cell. The methods of forming one device level have been explained above. Additional memory levels can be formed above or below the memory level described above to form a monolithic three dimensional memory array having more than one device level.

Based upon the teachings of this disclosure, it is expected that one of ordinary skill in the art will be readily able to practice the present invention. The descriptions of the various embodiments provided herein are believed to provide ample insight and details of the present invention to enable one of ordinary skill to practice the invention. Although certain supporting circuits and fabrication steps are not specifically described, such circuits and protocols are well known, and no particular advantage is afforded by specific variations of such steps in the context of practicing this invention. Moreover, it is believed that one of ordinary skill in the art, equipped with the teaching of this disclosure, will be able to carry out the invention without undue experimentation.

The foregoing details description has described only a few of the many possible implementations of the present invention. For this reason, this detailed description is intended by way of illustration, and not by way of limitations. Variations and modifications of the embodiments disclosed herein may be made based on the description set forth herein, without departing from the scope and spirit of the invention. It is only the following claims, including all equivalents, that are intended to define the scope of this invention.

What is claimed is:

1. A non-volatile memory cell, comprising:
a first electrode;
a steering element;
a storage element located in series with the steering element;
a plurality of discrete conductive nano-features separated from each other by an insulating matrix, wherein the plurality of discrete nano-features are located in direct contact with the storage element; and
a second electrode.

2. The non-volatile memory cell of claim 1, wherein the plurality of discrete conductive nano-features comprise semiconductor nanodots, metal nanodots, or metal alloy nanodots.

3. The non-volatile memory cell of claim 1, wherein the plurality of discrete conductive nano-features comprise metal nanodots which have a substantially spherical shape and a diameter of less than 20 nm.

4. The non-volatile memory cell of claim 2, wherein the metal nanodots have a curved contact area of about 2 nm to about 3 nm with the storage element.

5. The non-volatile memory cell of claim 2, wherein the metal nanodots comprise noble metal nanodots.

6. The non-volatile memory cell of claim 1, wherein:
the switching mechanism of the non-volatile memory cell is formation of filaments through the storage element; and
the filaments are only formed through the storage element adjacent to the discrete conductive nano-features when the non-volatile memory cell is programmed.

7. The non-volatile memory cell of claim 1, wherein:
the steering element is located above the first electrode;
the storage element is located above the steering element;
the plurality of discrete conductive nano-features and the insulating matrix are located above and in direct contact with the storage element; and
the second electrode is located above the plurality of discrete conductive nano-features.

8. The non-volatile memory cell of claim 1, wherein:
the plurality of discrete conductive nano-features and the insulating matrix are located above the first electrode;
the storage element is located above and in direct contact with the plurality of discrete conductive nano-features and the insulating matrix;
the steering element is located above the storage element; and
the second electrode is located above the steering element.

9. The non-volatile memory cell of claim 1, wherein the steering element is located either above or below the storage element, and the plurality of discrete conductive nano-features and the insulating matrix are located between the storage element and the steering element.

10. The non-volatile memory cell of claim 1, wherein the storage element is a resistivity switching material.

11. The non-volatile memory cell of claim 1, wherein the steering element comprises a diode and the storage element comprises at least one of switchable metal oxide, complex metal oxide layer, carbon nanotube material, graphene resistivity switchable material, carbon resistivity switchable material, phase change material, conductive bridge element, or switchable polymer material.

12. The non-volatile memory cell of claim 11, wherein:
the steering element comprises a p-i-n polysilicon diode;
the non-volatile memory cell is a rewritable memory cell; and
the non-volatile memory cell is located in a monolithic three dimensional array of memory cells.

13. The non-volatile memory cell of claim 11, wherein the storage element comprises at least one material selected from the group consisting of NiO, Nb₂O₅, TiO₂, HfO₂, Al₂O₃, MgOₓ, CrO₂, or VO.

14. The non-volatile memory cell of claim 1, wherein the plurality of discrete conductive nano-features comprise metal nanodots which have a substantially spherical shape and a diameter of less than 20 nm, the steering element comprises a diode, and the storage element comprises a switchable metal oxide layer.

15. A method of making a non-volatile memory cell, comprising:
forming a first electrode;
forming a steering element;
forming a storage element;
forming a plurality of discrete conductive nano-features separated from each other by an insulating matrix, wherein the plurality of discrete conductive nano-features are located in direct contact with the storage element; and
forming a second electrode.

16. The method of claim 15, wherein the plurality of discrete conductive nano-features comprise semiconductor nanodots, metal nanodots, or metal alloy nanodots.

17. The method of claim 15, wherein the plurality of discrete conductive nano-features comprise metal nanodots which have a substantially spherical shape and a diameter of less than 20 nm, the steering element comprises a diode, and the storage element comprises a switchable metal oxide layer.

18. The method of claim 15, wherein the step of forming the plurality of discrete conductive nano-features separated from each other by the insulating matrix comprises:
forming the plurality of conductive nano-features separated from each other;
forming an insulating layer over and between the plurality of discrete conductive nano-features; and
etching an upper portion of the insulating layer to expose the plurality of conductive nano-features, wherein a lower portion of the insulating layer remains between the plurality of conductive nano-features after the step of etching the upper portion of the insulating layer to form the insulating matrix.

19. The method of claim 18, wherein the step of forming the insulating layer comprise a low temperature and conformal deposition of a silicon oxide layer.

20. The method of claim 15, wherein:
the steering element is located above the first electrode;
the storage element is located above the steering element;
the plurality of discrete conductive nano-features and the insulating matrix are located above and in direct contact with the storage element; and
the second electrode is located above the plurality of discrete conductive nano-features.

21. The method of claim 15, wherein:
the plurality of discrete conductive nano-features and the insulating matrix are located above the first electrode;
the storage element is located above and in direct contact with the plurality of discrete conductive nano-features and the insulating matrix;
the steering element is located above the storage element; and
the second electrode is located above the steering element.

22. The method of claim 15, wherein the steering element is located either above or below the storage element, and the plurality of discrete conductive nano-features and the insulating matrix are located between the storage element and the steering element.

23. The method of claim 15, wherein the storage element is a resistivity switching material.

24. A non-volatile memory cell, comprising:
a first electrode;
a steering element;
a storage element located in series with the steering element;
a plurality of discrete insulating nano-features separated from each other by a conductive matrix, wherein the plurality of discrete insulating nano-features are located in direct contact with the storage element; and
a second electrode.

25. The non-volatile memory cell of claim 24, wherein the plurality of discrete insulating nano-features comprise silicon oxide nanoparticles which have a substantially spherical shape and a diameter of less than 20 nm.

26. The non-volatile memory cell of claim 24, wherein:
the switching mechanism of the non-volatile memory cell is formation of filaments through the storage element; and
the filaments are only formed through the storage element adjacent to the conductive matrix when the non-volatile memory cell is programmed.

27. The non-volatile memory cell of claim 24, wherein:
the steering element is located above the first electrode;
the storage element is located above the steering element;
the plurality of discrete insulating nano-features and the conductive matrix are located above and in direct contact with the storage element; and
the second electrode is located above and in direct contact with the conductive matrix.

28. The non-volatile memory cell of claim 24, wherein:
the conductive matrix is located above and in direct contact with the first electrode;
the storage element is located above and in direct contact with the conductive matrix and the plurality of discrete insulating nano-features;
the steering element is located above the storage element; and
the second electrode is located above the steering element.

29. The non-volatile memory cell of claim 24, wherein the steering element is located either above or below the storage element, and the plurality of discrete insulating nano-features and the conductive matrix are located between the storage element and the steering element.

30. The non-volatile memory cell of claim 24, wherein the storage element is a resistivity switching material.

31. The non-volatile memory cell of claim 30, wherein the steering element comprises a diode and the storage element comprises at least one of switchable metal oxide, complex metal oxide layer, carbon nanotube material, graphene resistivity switchable material, carbon resistivity switchable material, phase change material, conductive bridge element, or switchable polymer material.

32. The non-volatile memory cell of claim 31, wherein:
the steering element comprises a p-i-n polysilicon diode;
the non-volatile memory cell is a rewritable memory cell;
the non-volatile memory cell is located in a monolithic three dimensional array of memory cells; and
the storage element comprises at least one material selected from the group consisting of NiO, Nb₂O₅, TiO₂, HfO₂, Al₂O₃ , MgOₓ, CrO₂, or VO.

33. A method of making a non-volatile memory cell, comprising:
forming a first electrode;
forming a steering element;
forming a storage element;
forming a plurality of discrete insulating nano-features separated from each other by a conductive matrix, wherein the plurality of discrete insulating nano-features and the conductive matrix are located in direct contact with the storage element; and
forming a second electrode.

34. The method of claim 33, wherein the step of forming the plurality of discrete insulating nano-features separated from each other by the conductive matrix comprises:
forming the plurality of discrete insulating nano-features separated from each other; and
forming the conductive matrix over and between the plurality of discrete insulating nano-features.

35. The method of claim 33, wherein the plurality of discrete insulating nano-features comprise silicon oxide nanoparticles which have a substantially spherical shape.

36. The method of claim 33, wherein the storage element is a resistivity switching material.

37. The method of claim 36, wherein the steering element comprises a diode and the storage element comprises a switchable metal oxide layer.

38. The method of claim 33, wherein:
the steering element is located above the first electrode;
the storage element is located above the steering element;
the plurality of discrete insulating nano-features and the conductive matrix are located above and in direct contact with the storage element; and
the second electrode is located above and in direct contact with the conductive matrix.

39. The method of claim 33, wherein the steering element is located either above or below the storage element, and the plurality of discrete insulating nano-features and the conductive matrix are located between the storage element and the steering element.

40. The method of claim 33, wherein:
the conductive matrix is located above and in direct contact with the first electrode;
the storage element is located above and in direct contact with the conductive matrix and the plurality of discrete insulating nano-features;
the steering element is located above the storage element; and
the second electrode is located above the steering element.
